(19) United States
(12) Patent Application Publication
(10) Pub. No.: US 2022/0121393 A1
(43) Pub. Date: Apr. 21, 2022

(54) BUFFER MANAGEMENT OF MEMORY REFRESH

(71) Applicant: Brent Keeth, Boise, ID (US)

(72) Inventor: Brent Keeth, Boise, ID (US)

(21) Appl. No.: 17/506,405

(22) Filed: Oct. 20, 2021

Related U.S. Application Data
(60) Provisional application No. 63/094,725, filed on Oct. 21, 2020.

(51) Int. Cl. G06F 3/06

(52) U.S. Cl. CPC G06F 3/0656; G06F 3/0673; G06F 3/0604

(57) ABSTRACT

Techniques for refreshing memory cells of a stack of random-access memory are provided. In an example, a method can include exchanging data between a host processor and a buffer die at a first data speed, exchanging data between the buffer die and one or more DRAM dies at a second speed, slower than the first speed, and controlling refresh of the one or more DRAM dies via a controller of the buffer die.

### PRIORITY APPLICATION

This application claims the benefit of priority to U.S. Application Ser. No. 63/094,725, filed Oct. 21, 2020, which is incorporated herein by reference in its entirety.

### TECHNICAL FIELD

The present description relates generally to example structures and methods for a first memory interface to multiple respective second memory interfaces for interfacing with one or more memory devices, and more particularly, a buffer (in some examples, a buffer die or buffer assembly), operable to perform such reallocation. In some examples, the buffer can be configured to perform refresh operations so as to reduce an operational burden of a connected host device.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface). The memory controller can receive commands or operations from the host system in association with memory operations or instructions, such as read or write operations to transfer data (e.g., user data and associated integrity data, such as error data or address data, etc.) between the memory devices and the host device, erase operations to erase data from the memory devices, perform drive management operations (e.g., data migration, garbage collection, block retirement), etc.

It is desirable to provide improved main memory, such as DRAM memory. Features of improved main memory that are desired include, but are not limited to, higher capacity, higher speed, and reduced cost.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A illustrates a system including a memory device in accordance with some example embodiments.

FIG. 1B illustrates another system including a memory device in accordance with some example embodiments.

FIG. 2 illustrates an example memory device in accordance with some example embodiments.

FIG. 3 illustrates generally an example buffer die in block diagram form in accordance with some example embodiments.

FIG. 4 illustrates another memory device in accordance with some example embodiments.

FIG. 5A illustrates another memory device in accordance with some example embodiments.

FIG. 5B illustrates another memory device in accordance with some example embodiments.

FIG. 5C illustrates another memory device in accordance with some example embodiments.

FIG. 5D illustrates another memory device in accordance with some example embodiments.

FIG. 6 illustrates another memory device in accordance with some example embodiments.

FIG. 7 illustrates another memory device in accordance with some example embodiments.

FIG. 8A illustrates another memory device in accordance with some example embodiments.

FIG. 8B illustrates another memory device in accordance with some example embodiments.

FIG. 9 illustrates generally an example buffer die in block diagram form in accordance with some example embodiments.

FIG. 10 illustrates generally an example method of operating a buffer die.

FIG. 11 illustrates a block diagram of an example machine such as a host system which may include an example buffer die or memory systems according to the present subject matter

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Described below are various embodiments incorporating memory systems in which an external memory interface operates to transfer data at a first rate, but the memory operates internally at a second data rate slower than the first data rate. In examples described below, such operation can be achieved through use of a buffer interface in communication with the external memory interface (which may be, for example, a host interface), and redistributes the data connections (DQs) of the external interface to a greater number of data connections in communication with one or more memory devices (and/or one or more memory banks), and which operate at a slower clock rate than that of the external memory interface.

In embodiments as described below, the buffer interface may be presented in a separate die sitting between a host (or other) interface and one or more memory die. In an example embodiment, a buffer die (or other form of buffer interface) may include a host physical interface including connections for at least one memory channel (or sub-channel), including bidirectional command/address connections and bidirectional data connections. Control logic in the buffer interface may be implemented to reallocate the connections for the memory channel to at least two (or more) memory sub-channels, which connections extend to DRAM physical interfaces for each sub-channel, each sub-channel physical interface including command/address connections and data connections. The DRAM physical interfaces for each sub-channel then connect with one or more memory die.

Also described below are stacked memory structures as may be used in one of the described memory systems, in which multiple memory die may be laterally offset from one another and connected either with another memory die, a logic die, or another structure/device, through wire bond connections. As described below, in some examples, one or more of the memory die may include redistribution layers (RDLs) to distribute contact pads proximate an edge of the die to facilitate the described wire bonding.

In some embodiments, a buffer interface as described above may be used to reallocate a host (or other) interface including DQs, including data connections, multiple ECC connections, and multiple parity connections. In some such embodiments, the buffer interface may be used in combination with one or more memory devices configured to allocate the data, ECC, and parity connections within the memory device(s) in a manner to protect against failure within the portion of the memory array or data path associated with a respective DRAM physical interface, as discussed in more detail below. This failure protection can be implemented in a manner to improve reliability of the memory system in a manner generally analogous to techniques known to the industry as Chipkill (trademark of IBM), or Single Device Data Correction (SDDC) (trademark of Intel). Such failure protection can be implemented to recover from multi-bit errors, for example as those affecting a region (such as a sub-channel or sub-array) of a memory, as will be apparent to persons skilled in the art having the benefit of the present disclosure.

In certain examples, a buffer interface as described above may be used to offset some of the processing tasks of a connected host device. One such processing task can include memory refresh. Memory refresh is the process of periodically reading information from an area of memory and immediately rewriting the information to the same area without modification, for the purpose of preserving the information. Memory refresh is a background maintenance process required during the operation of semiconductor dynamic random-access memory (DRAM) as well as other types of memory. While the memory is operating, retention of the information of the memory can rely on each memory cell periodically being refreshed, within the maximum interval between refreshes specified by the manufacturer, which is usually in the millisecond region but can be longer or shorter without departing from the scope of the present subject matter. Refresh operations of a host device can represent a substantial portion of the processing time available to the host device. In addition, DRAM memory is refreshed even when the processor is sleeping or in a low-power mode and the power consumed by the host for refresh operations can be significant. Offloading at least a portion of the refresh tasks to for example a buffer interface can save power, especially during low power modes of the host, and can free up processing resources for other modes of operation.

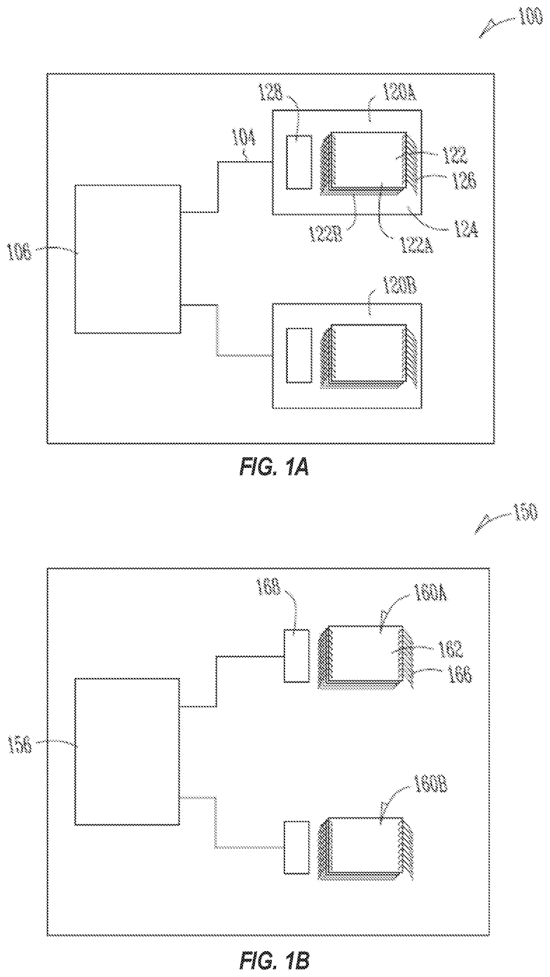

FIG. 1A shows an electronic system 100, having a processor 106 coupled to a substrate 102. In some examples substrate 102 can be a system motherboard, or in other examples, substrate 102 may couple to another substrate, such as a motherboard. Electronic system, 100 also includes first and second memory devices 120A, 120B. Memory devices 120A, 120B are also shown supported by substrate 102 adjacent to the processor 106 but are depicted, in an example configuration, coupled to a secondary substrate 124. In other examples, memory devices 120A, 120B can be coupled directly to the same substrate 102 as processor 106.

The memory devices 120A, 120B, each include a buffer assembly, here in the example form of a buffer die 128, coupled to a secondary substrate 124. The memory devices 120A, 120B can be individual die, or in some cases may each include a respective stack of memory devices 122. For purposes of the present description, memory devices 120A, 120B will be described in an example configuration of stacked memory devices. Additionally, memory devices 120A, 120B will be described in one example configuration in which the devices are dynamic random access memory (DRAM) dies 122A, 122B are each coupled to the secondary substrate 124. Other types of memory devices may be used in place of DRAM, including, for example FeRAM, phase change memory (PCM), 3D XPoint™ memory, NAND memory, or NOR memory, or a combination thereof. In some cases, a single memory device may include one or more memory die that uses a first memory technology (e.g., DRAM) and a second memory die that uses a second memory technology (e.g., SRAM, FeRAM, etc.) different from the first memory technology.

The stack of DRAM dies 122 are shown in block diagram form in FIG. 1. Other figures in the following description shown greater detail of the stack of dies and various stacking configurations. In the example of FIG. 1A, a number of wire bonds 126 are shown coupled to the stack of DRAM dies 122. Additional circuitry (not shown) is included on or within the substrate 124. The additional circuitry completes the connection between the stack of DRAM dies 122, through the wire bonds 126, to the buffer die 120. Selected examples may include through silicon vias (TSVs) instead of wire bonds 126 as will be described in more detail in subsequent figures.

Substrate wiring 104 is shown coupling the memory device 120A to the processor 106. In the example of FIG. 16, an additional memory device 120B is shown. Although two memory devices 120A, 120B are shown for the depicted example, a, single memory structure may be used, or a number of memory devices greater than two may be used. Examples of memory devices as described in the present disclosure provide increased capacity near memory with increased speed and reduced manufacturing cost.

FIG. 1B shows an electronic system 150, having a processor 156 coupled to a substrate 152. The system 150 also includes first and second memory devices 160A, 160B. In contrast to FIG. 1A, in FIG. 1B, the first and second memory devices 160A, 160B are directly connected to the same substrate 102 as the processor 156, without any intermediary substrates or interposers. This configuration can provide additional speed and reduction in components over the example of FIG. 1A. Similar to the example of FIG. 1A, a buffer assembly or buffer die 168 is shown adjacent to a stack of DRAM dies 162. Wire bonds 166 are shown as an example interconnection structure, however other interconnection structures such as TSVs may be used.

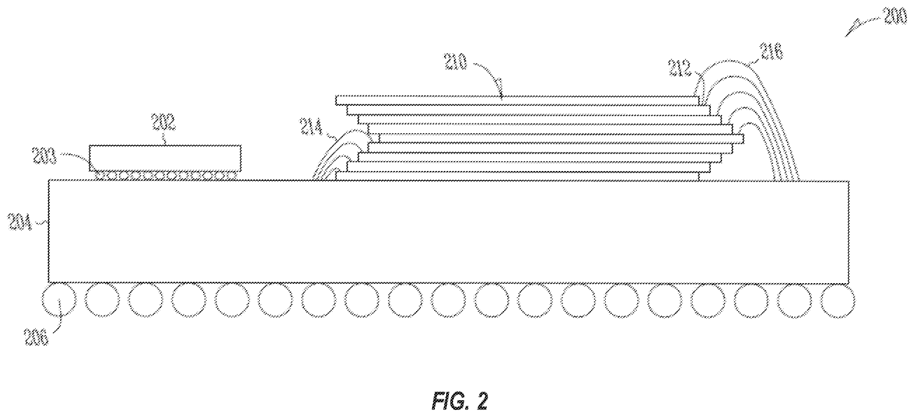

FIG. 2 shows a memory system 200 similar to memory device 118A or 118B from FIG. 1B. The memory device 200 includes a buffer die 202 coupled to a substrate 204. The memory device 200 also includes a stack of DRAM dies 210 coupled to the substrate 204. In the example of FIG. 2, the individual dies in the stack of DRAM dies 210 are laterally offset from one or more vertically adjacent die specifically, in the depicted example, each die is laterally offset from both vertically adjacent die. As an example, the die may be staggered in at least one stair step configuration. The Example of FIG. 2 shows two different stagger directions in the stair stepped stack of DRAM dies 210. In the illustrated dual stair step configuration, an exposed surface portion 212 of each die is used for a number of wire bond interconnections.

Multiple wire bond interconnections 214, 216 are shown from the dies in the stack of DRAM dies 210 to the substrate 204. Additional conductors (not shown) on or within the substrate 204 further couple the wire bond interconnections 214, 216 to the buffer die 202. The buffer die 202 is shown coupled to the substrate 204 using one or more solder interconnections 203, such as a solder ball array. A number of substrate solder interconnections 206 are further shown on a bottom side of the substrate 204 to further transmit signals and data from the buffer die into a substrate 102 and eventually to a processor 106 as shown in FIG. 1B.

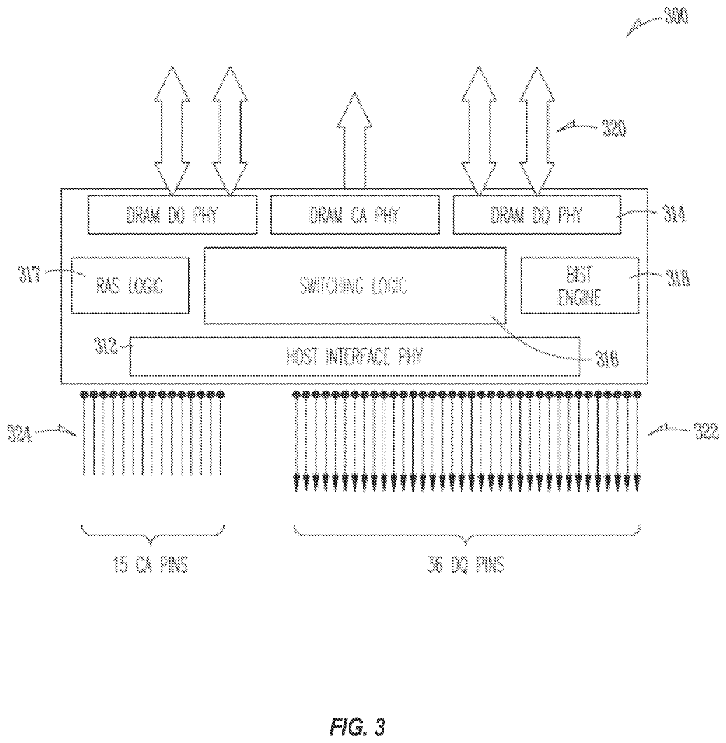

FIG. 3 shows a block diagram of a buffer die 300 similar to buffer die 202 from FIG. 2. A host device interface 312 and a DRAM interface 314 are shown. Additional circuitry components of the buffer die 300 may include a switching logic 316; reliability, availability, and serviceability (RAS) logic 317; and built-in self-test (BIST) logic 318. Communication from the buffer die 300 to a stack of DRAM dies is indicated by arrows 320. Communication from the buffer die 300 to a host device is indicated by arrows 322 and 324. In FIG. 3, arrows 322 denote unidirectional or bidirectional communication via command/address (CA) pins, and arrows 324 denote unidirectional or bidirectional communication via data (DQ) pins 322. Example numbers of CA pins and DQ pins are provided only as examples, as the host device interface may have substantially greater or fewer of either or both CA and DQ pins. The number of pins of either type required may vary depending upon the width of the channel of the interface, the provision for additional bits (for example ECC bits), among many other variables. In many examples, the host device interface will be an industry standard memory interface (either expressly defined by a standard-setting organization, or a de facto standard adopted in the industry).

In one example, all CA pins 324 act as a single channel, and all data pins 322 act as a single channel. In one example, all CA pins service all data pins 322. In another example, the CA pins 324 are subdivided into multiple sub-channels. In another example, the data pins 322 are subdivided into multiple sub-channels. One configuration may include a portion of the CA pins 324 servicing a portion of the data pins 322. In one specific example, 8 CA pins service 9 data (DQ) pins as a sub-combination of CA pins and data (DQ) pins. Multiple sub-combinations such as the 8 CA pin/9 data pin example, may be included in one memory device.

It is common in computing devices to have DRAM memory coupled to a substrate, such as a motherboard, using a socket, such as a dual in line memory (DIMM) socket. However, a physical layout of DRAM chips and socket connections on a DIMM device takes up a large amount of space. It is desirable to reduce an amount of space for DRAM memory. Additionally, communication through a socket interface is slower and less reliable than direct connection to a motherboard using solder connections. The additional component of the socket interface adds cost to the computing device.

Using examples of memory devices in the present disclosure, a physical size of a memory device is reduced for a given DRAM memory capacity. Speed is improved due to the direct connection to the substrate, and cost is reduced by eliminating the socket component.

In operation, a possible data speed from a host device may be higher than interconnection components to DRAM dies such as trace lines, TSVs, wire bonds, etc. can handle. The addition of a buffer die 300 (or other form of buffer assembly) allows fast data interactions from a host device to be buffered. In the example of FIG. 3, the host interface 312 is configured to operate at a first data speed. In one example, the first data speed may match the speed that the host device is capable of delivering.

In one example, the DRAM interface 314 is configured to operate at a second data speed, slower than the first data speed. In one example, the DRAM interface 314 is configured to be both slower and wider than the host interface 312. In operation, the buffer die may translate high speed data interactions on the host interface 312 side into slower, wider data interactions on the DRAM interface 314 side. Additionally, as further described below, to maintain data throughput at least approximating that of the host interface, in some examples, the buffer assembly can reallocate the connections of the host interface to multiple sub-channels associated with respective DRAM interfaces. The slower, and wider DRAM interface 314 may be configured to substantially match the capacity of the narrower, higher speed host interface 312. In this way, more limited interconnection components to DRAM dies such as trace lines, TSVs, wire bonds, etc. are able to handle the capacity of interactions supplied from the faster host device. Though one example host interface (with both CA pins and DQ pins) to buffer die 300 is shown, buffer die 300 may include multiple host interfaces for separate data paths that are each mapped by buffer die 300 to multiple DRAM interfaces, in a similar manner.

In one example, the host device interface 312 includes a first number of data paths, and the DRAM interface 314 includes a second number of data paths greater than the first number of data paths. In one example, circuitry in the buffer die 300 maps data and commands from the first number of data paths to the second number of data paths. In such a configuration, the second number of data paths provide a slower and wider interface, as described above.

In one example the command/address pins 324 of the host device interface 312 include a first number of command/address paths, and on a corresponding DRAM interface 314 side of the buffer die 300, the DRAM interface 314 includes a second number of command/address paths that is larger than the first number of command/address paths. In one example, the second number of command/address paths is twice the first number of command/address paths. In one example, the second number of command/address paths is more than twice the first number of command/address paths. In one example, the second number of command/address paths is four times the first number of command/address paths. In one example, the second number of command/address paths is eight times the first number of command/address paths.

In one example, a given command/address path on the DRAM interface 314 side of the buffer die 300 is in communication with only a single DRAM die. In one example, a given command/address path on the DRAM interface 314 side of the buffer die 300 is in communication with multiple DRAM dies. In one example, a given command/address path on the DRAM interface 314 side of the buffer die 300 is in communication with 4 DRAM dies. In one example, a given command/address path on the DRAM interface 314 side of the buffer die 300 is in communication with 16 DRAM dies.

In one example the data pins 322 of the host device interface 312 include a first number of data paths, and on a corresponding DRAM interface 314 side of the buffer die 300, the DRAM interface 314 includes a second number of data paths that is larger than the first number of data paths. In one example, the second number of data paths is twice the first number of data paths. In one example, the second number of data paths is more than twice the first number of data paths. In one example, the second number of data paths is four times the first number of data paths. In one example, the second number of data paths is eight times the first number of data paths.

In one example, a data path on the DRAM interface 314 side of the buffer die 300 is in communication with only a single DRAM die. In one example, a given data path on the DRAM interface 314 side of the buffer die 300 is in communication with multiple DRAM dies. In one example, a given data path on the DRAM interface 314 side of the buffer die 300 is in communication with 4 DRAM dies. In one example, a given data path on the DRAM interface 314 side of the buffer die 300 is in communication with 16 DRAM dies.

In one example, the host interface 312 includes different speeds for command/address pins 324, and for data pins 322. In one example, data pins 322 of the host interface are configured to operate at 6.4 Gb/s. In one example, command/address pins 324 of the host interface are configured to operate at 3.2 Gb/s.

In one example, the DRAM interface 314 of the buffer die 300 slows down and widens the communications from the host interface 312 side of the buffer die 300. In one example, where a given command/address path from the host interface 312 is mapped to two command/address paths on the DRAM interface 314, a speed at the host interface is 3.2 Gb/s, and a speed at the DRAM interface 314 is 1.6 Gb/s.

In one example, where a given data path from the host interface 312 is mapped to two data paths on the DRAM interface 314, a speed at the host interface is 6.4 Gb/s, and a speed at the DRAM interface 314 is 3.2 Gb/s, where each data path is in communication with a single DRAM die in a stack of DRAM dies. In one example, where a given data path from the host interface 312 is mapped to four data paths on the DRAM interface 314, a speed at the host interface is 6.4 Gb/s, and a speed at the DRAM interface 314 is 1.6 Gb/s, where each data path is in communication with four DRAM dies in a stack of DRAM dies. In one example, where a given data path from the host interface 312 is mapped to eight data paths on the DRAM interface 314, a speed at the host interface is 6.4 Gb/s, and a speed at the DRAM interface 314 is 0.8 Gb/s, where each data path is in communication with 16 DRAM dies in a stack of DRAM dies.

In one example, a pulse amplitude modulation (PAM) protocol is used to communicate on the DRAM interface 314 side of the buffer die 300. In one example, the PAM protocol includes PAM-4, although other PAM protocols are within the scope of the invention. In one example, the PAM protocol increases the data bandwidth. In one example, where a given data path from the host interface 312 is mapped to four data paths on the DRAM interface 314, a speed at the host interface is 6.4 Gb/s, and a speed at the DRAM interface 314 is 0.8 Gb/s using a PAM protocol, where each data path is in communication with four DRAM dies in a stack of DRAM dies. In one example, where a given data path from the host interface 312 is mapped to eight data paths on the DRAM interface 314, a speed at the host interface is 6.4 Gb/s, and a speed at the DRAM interface 314 is 0.4 Gb/s using a PAM protocol, where each data path is in communication with 16 DRAM dies in a stack of DRAM dies.

A number of pins needed to communicate between the buffer die 300 and an example 16 DRAM dies varies depending on the number of command/address paths on the DRAM interface 314 side of the buffer die 300, and on the number of DRAM dies coupled to each data path. The following table show a number of non-limiting examples of pin counts and corresponding command/address path configurations.

| | | | DRAM | # dies | |
|---|---|---|---|---|---|
| host CA | host speed | DRAM CA | speed | coupled to | # |
| paths | (Gb/s) | paths | (Gb/s) | DRAM path | pins |
| 15 | 3.2 | 30 | 1.6 | 16 | 480 |
| 15 | 3.2 | 30 | 1.6 | 4 | 120 |
| 15 | 3.2 | 30 | 1.6 | 16 | 30 |
| 15 | 3.2 | 30 | 0.8 PAM-4 | 4 | 120 |
| 15 | 3.2 | 30 | 0.8 PAM-4 | 16 | 30 |

A number of pins needed to communicate between the buffer die 300 and an example 16 DRAM dies varies depending on the number of data paths on the DRAM interface 314 side of the buffer die 300, and on the number of DRAM dies coupled to each data path. The following table show a number of non-limiting examples of pin counts and corresponding data path configurations.

| | | | DRAM | # dies | |
|---|---|---|---|---|---|
| host data | host speed | DRAM data | speed | coupled to | # |
| paths | (Gb/s) | paths | (Gb/s) | DRAM path | pins |
| 36 | 6.4 | 72 | 3.2 | 1 | 1152 |
| 36 | 6.4 | 144 | 1.6 | 4 | 576 |
| 36 | 6.4 | 288 | 0.8 | 16 | 288 |
| 36 | 6.4 | 144 | 0.8 PAM-4 | 4 | 576 |
| 36 | 6.4 | 288 | 0.4 PAM-4 | 16 | 288 |

As illustrated in selected examples below, the number of pins in the above tables may be coupled to the DRAM dies in the stack of DRAM dies in a number of different ways. In one example, wire bonds are used to couple from the pins to the number of DRAM dies. In one example, TSVs are used to couple from the pins to the number of DRAM dies. Although wire bonds and TSVs are used as an example, other communication pathways apart from wire bonds and TSVs are also within the scope of the invention.

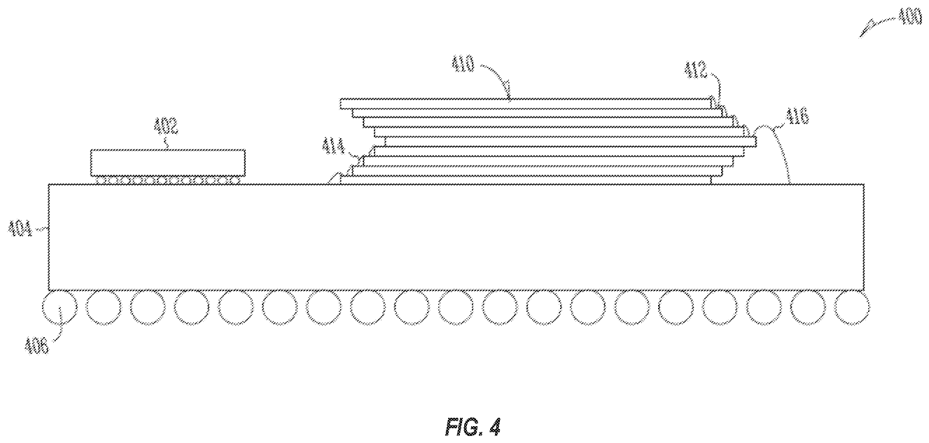

FIG. 4 shows another example of a memory device 400. The memory device 400 includes a buffer die 402 coupled to a substrate 404. The memory device 400 also includes a stack of DRAM dies 410 coupled to the substrate 404. In the example of FIG. 4, the stack of DRAM dies 410 are staggered in at least one stair step configuration. The Example of FIG. 4 shows two different stagger directions in the stair stepped stack of DRAM dies 410. Similar to the configuration of FIG. 2, in the illustrated stair step configuration, an exposed surface portion 412 is used for a number of wire bond interconnections.

Multiple wire bond interconnections 414, 416 are shown from the dies in the stack of DRAM dies 410 to the substrate 404. Additional conductors (not shown) on or within the substrate 404 further couple the wire bond interconnections 414, 416 to the buffer die 402. The buffer die 402 is shown coupled to the substrate 404 using one or more solder interconnections, such as a solder ball array. A number of substrate solder interconnections 406 are further shown on a bottom side of the substrate 404 to further transmit signals and data from the buffer die into a motherboard and eventually to a host device.

In the example of FIG. 4, the multiple wire bond interconnections 414, 416 are serially connected up the multiple stacked DRAM dies. In selected examples, a single wire bond may drive a load in more than one DRAM die. In such an example, the wire bond interconnections may be serially connected as shown in FIG. 4. In one example, a single wire bond may be serially connected to four DRAM dies. In one example, a single wire bond may be serially connected to eight DRAM dies. In one example, a single wire bond may be serially connected to sixteen DRAM dies. Other numbers of serially connected DRAM dies are also within the scope of the invention. Additionally, CA connections of the DRAM interface may be made to a first number of the DRAM dies, while the corresponding DQ connections of the DRAM interface may be made to a second number of the DRAM dies different from the first number.

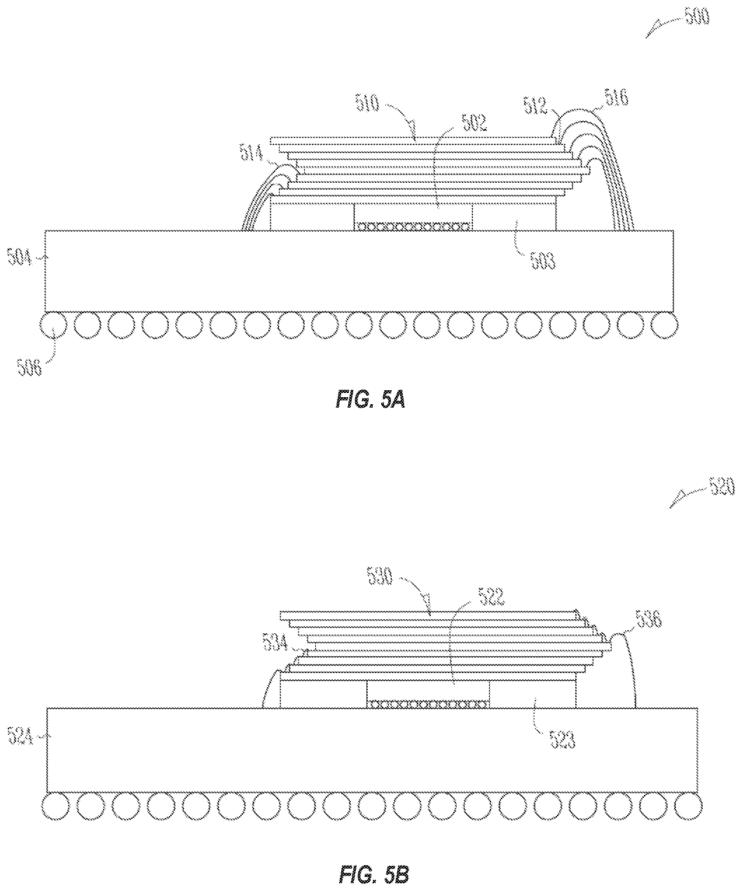

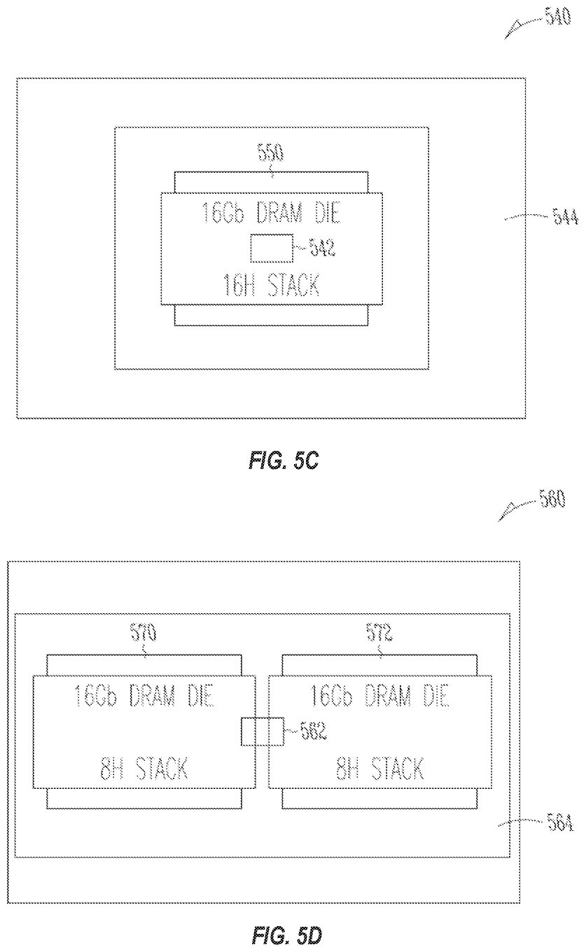

FIG. 5A shows another example of a memory device 500. The memory device 500 includes a buffer die 502 coupled to a substrate 504. The memory device 500 also includes a stack of DRAM dies 510 coupled to the substrate 504. In the example of FIG. 5A, the stack of DRAM dies 510 are staggered in at least one stair step configuration. The Example of FIG. 5 shows two different stagger directions in the stair stepped stack of DRAM dies 510. In the illustrated stair step configuration, an exposed surface portion 512 is used for a number of wire bond interconnections.

Multiple wire bond interconnections 514, 516 are shown from the dies in the stack of DRAM dies 410 to the substrate 404. Additional conductors (not shown) on or within the substrate 504 further couple the wire bond interconnections 514, 451616 to the buffer die 502. The buffer die 502 is shown coupled to the substrate 504 using one or more solder interconnections, such as a solder ball array. A number of substrate solder interconnections 506 are further shown on a bottom side of the substrate 504 to further transmit signals and data from the buffer die into a motherboard and eventually to a host device.

In the example of FIG. 5A, the buffer die 502 is located at least partially underneath the stack of DRAM dies 510. In one example, an encapsulant 503 at least partially surrounds the buffer die 502. The example of FIG. 5A further reduces a real footprint of the memory device 500. Further, an interconnect distance between the stack of DRAM dies 510 and the buffer die 502 is reduced.

FIG. 5B shows another example of a memory device 520. The memory device 520 includes a buffer die 522 coupled to a substrate 524. The memory device 520 also includes a stack of DRAM dies 530 coupled to the substrate 524. Multiple wire bond interconnections 534, 536 are shown from the dies in the stack of DRAM dies 530 to the substrate 524. In the example of FIG. 5B, the multiple wire bond interconnections 534, 536 are serially connected up the multiple stacked DRAM dies. In one example, a single wire bond may be serially connected to four DRAM dies. In one example, a single wire bond may be serially connected to eight DRAM dies. In one example, a single wire bond may be serially connected to sixteen DRAM dies. Other numbers of serially connected DRAM dies are also within the scope of the invention.

FIG. 5C shows a top view of a memory device 540 similar to memory devices 500 and 520. In the example of FIG. 5C, a buffer die 542 is shown coupled to a substrate 544, and located completely beneath a stack of DRAM dies 550. FIG. 5D shows a top view of a memory device 560 similar to memory devices 500 and 520. In FIG. 5D, a buffer die 562 is coupled to a substrate 564, and located partially underneath a portion of a first stack of DRAM dies 570 and a second stack of DRAM dies 572. In one example, a shorter stack of DRAM dies provides a shorter interconnection path, and a higher manufacturing yield. In selected examples, it may be desirable to use multiple shorter stacks of DRAM dies for these reasons. One tradeoff of multiple shorter stacks of DRAM dies is a larger areal footprint of the memory device 560.

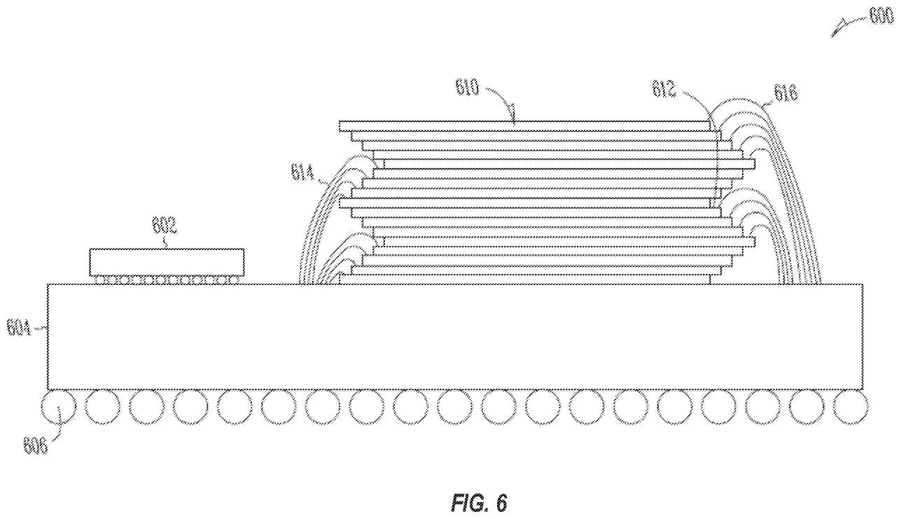

FIG. 6 shows another example of a memory device 600. The memory device 600 includes a buffer die 602 coupled to a substrate 604. The memory device 600 also includes a stack of DRAM dies 610 coupled to the substrate 604. In the example of FIG. 6, the stack of DRAM dies 610 are staggered in at least one stair step configuration. The Example of FIG. 6 shows four staggers, in two different stagger directions in the stair stepped stack of DRAM dies 610. The stack of DRAM dies 610 in FIG. 6 includes 16 DRAM dies, although the invention is not so limited. Similar to other stair step configurations shown, in FIG. 6, an exposed surface portion 612 is used for a number of wire bond interconnections.

Multiple wire bond interconnections 614, 616 are shown from the dies in the stack of DRAM dies 610 to the substrate 604. Additional conductors (not shown) on or within the substrate 604 further couple the wire bond interconnections 614, 616 to the buffer die 602. The buffer die 602 is shown coupled to the substrate 604 using one or more solder interconnections, such as a solder ball array. A number of substrate solder interconnections 606 are further shown on a bottom side of the substrate 604 to further transmit signals and data from the buffer die into a motherboard and eventually to a host device.

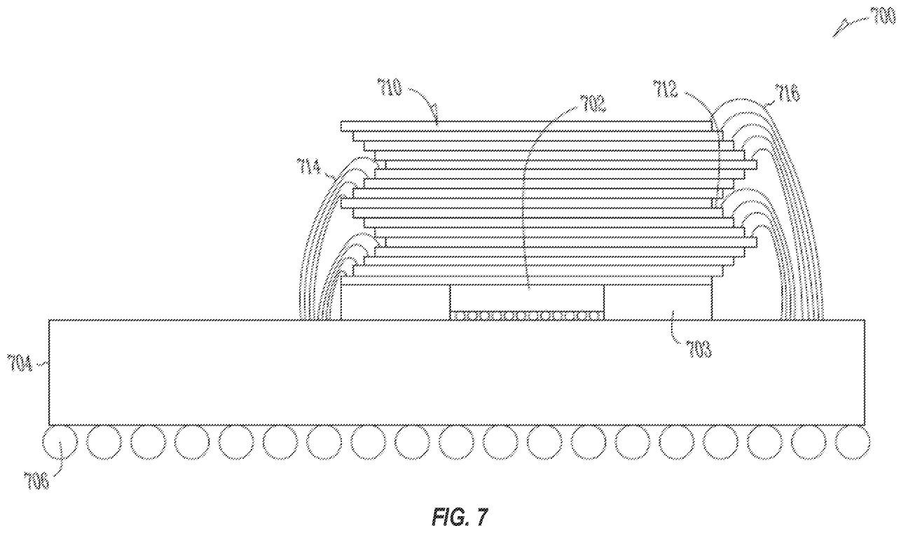

FIG. 7 shows another example of a memory device 700. The memory device 700 includes a buffer die 702 coupled to a substrate 704. The memory device 700 also includes a stack of DRAM dies 710 coupled to the substrate 704. In the example of FIG. 7, the stack of DRAM dies 710 are staggered in at least one stair step configuration. The Example of FIG. 7 shows four staggers, in two different stagger directions in the stair stepped stack of DRAM dies 710. The stack of DRAM dies 710 in FIG. 7 includes 16 DRAM dies, although the invention is not so limited. Similar to other stair step configurations shown, in FIG. 7, an exposed surface portion 712 is used for a number of wire bond interconnections.

Multiple wire bond interconnections 714, 716 are shown from the dies in the stack of DRAM dies 710 to the substrate 704. Additional conductors (not shown) on or within the substrate 704 further couple the wire bond interconnections 714, 716 to the buffer die 702. The buffer die 702 is shown coupled to the substrate 704 using one or more solder interconnections, such as a solder ball array. A number of substrate solder interconnections 706 are further shown on a bottom side of the substrate 704 to further transmit signals and data from the buffer die into a motherboard and eventually to a host device.

In the example of FIG. 7, the buffer die 702 is located at least partially underneath the stack of DRAM dies 710. In one example, an encapsulant 703 at least partially surrounds the buffer die 702. The example of FIG. 7 further reduces a real footprint of the memory device 700. Additionally, an interconnect distance between the stack of DRAM dies 710 and the buffer die 702 is reduced.

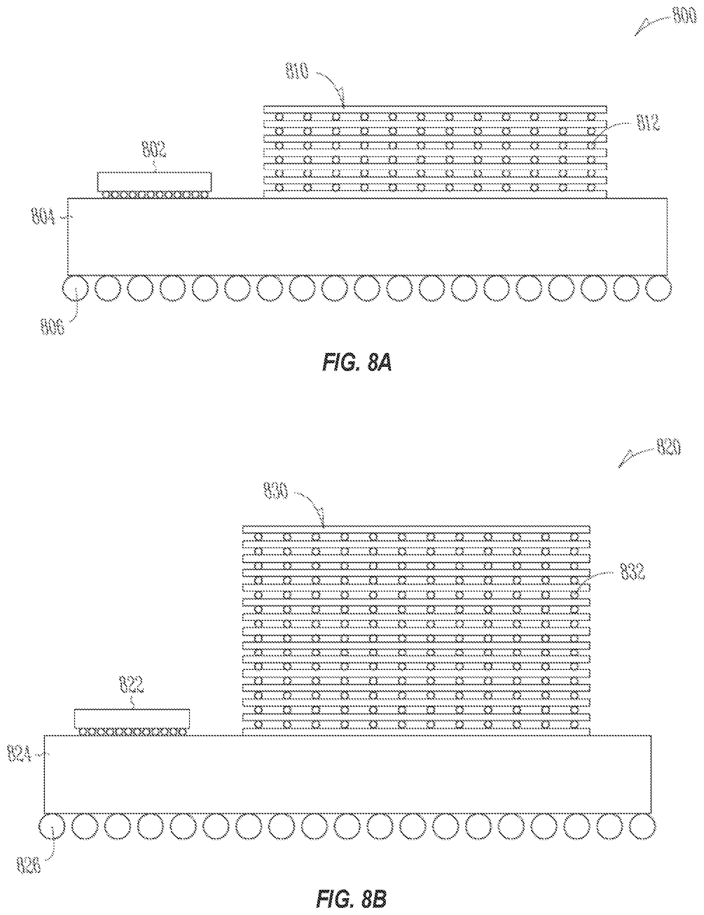

FIG. 8A shows another example of a memory device 800. The memory device 800 includes a buffer die 802 coupled to a substrate 804. The memory device 800 also includes a stack of DRAM dies 810 coupled to the substrate 804. In the example of FIG. 8A, the stack of DRAM dies 810 are vertically aligned. The stack of DRAM dies 810 in FIG. 8A includes 8 DRAM dies, although the invention is not so limited.

Multiple TSV interconnections 812 are shown passing through, and communicating with one or more dies in the stack of DRAM dies 810 to the substrate 804. Additional conductors (not shown) on or within the substrate 804 further couple the TSVs 812 to the buffer die 802. The buffer die 802 is shown coupled to the substrate 804 using one or more solder interconnections, such as a solder ball array. A number of substrate solder interconnections 806 are further shown on a bottom side of the substrate 804 to further transmit signals and data from the buffer die into a motherboard and eventually to a host device.

FIG. 8B shows another example of a memory device 820. The memory device 820 includes a buffer die 822 coupled to a substrate 824. The memory device 820 also includes a stack of DRAM dies 830 coupled to the substrate 824. In the example of FIG. 8B, the stack of DRAM dies 830 are vertically aligned. The stack of DRAM dies 830 in FIG. 8B includes 16 DRAM dies, although the invention is not so limited.

Multiple TSV interconnections 832 are shown passing through, and communicating with one or more dies in the stack of DRAM dies 830 to the substrate 824. Additional conductors (not shown) on or within the substrate 824 further couple the TSVs 832 to the buffer die 822. The buffer die 822 is shown coupled to the substrate 824 using one or more solder interconnections, such as a solder ball array. A number of substrate solder interconnections 826 are further shown on a bottom side of the substrate 824 to further transmit signals and data from the buffer die into a motherboard and eventually to a host device.

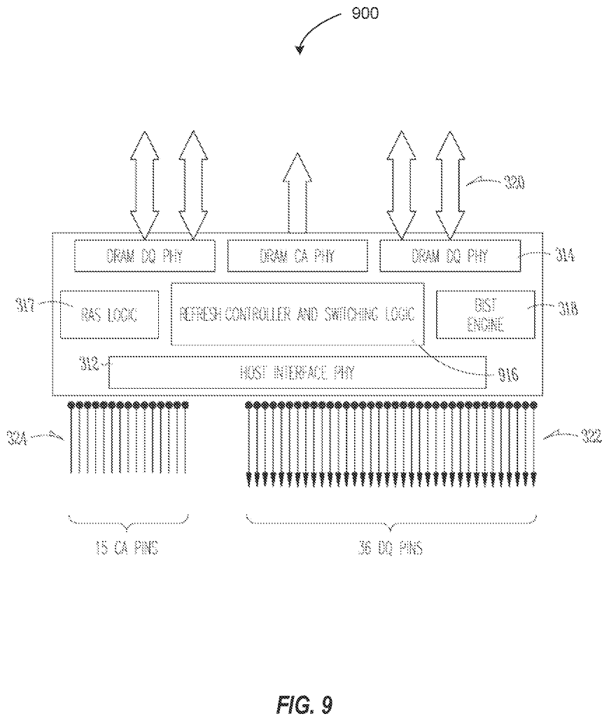

FIG. 9 illustrates generally an example buffer die 900 according to the present subject matter. The buffer die 902 can include the same functionality and features as the buffer die of the previous examples, including but not limited to the buffer die of FIG. 1A, 128; FIG. 1B, 168; FIG. 2, 202; FIG. 3, 300; FIG. 4, 400; FIG. 5A, 502; FIG. 5B, 522; FIG. 5C, 542; FIG. 5D, 562; FIG. 6, 602; FIG. 7, 702; FIG. 8A, 802; and FIG. 8B, 822. The buffer die 902 can include a host device interface 312 and a DRAM interface 314. Additional circuitry components of the buffer die 902 may include refresh and switching logic 916; reliability, availability, and serviceability (RAS) logic 317; and built-in self-test (BIST) logic 318. Communication from the buffer die 902 to a stack of DRAM dies is indicated by arrows 320. Communication from the buffer die 902 to a host device is indicated by arrows 322 and 324. In FIG. 9, arrows 322 can denote communication from command/address (CA) pins, and arrows 324 can denote communication from data (DQ) pins 322.

In certain examples, in addition to the functionality described above, the refresh controller 916 or refresh control circuitry can execute refresh operations of the DRAM memory. Execution of refresh operations can alleviate at least a portion a resource consuming task of a connected host device such as a memory controller. As such, the buffer die 900 can allow the connected device to provide better performance or use the freed-up resources to provide additional functionality. In certain examples, the refresh controller 916 can refresh a certain block of memory cells such as a rank of memory or a bank of memory. A rank of memory is typically associated with a chip select or chip ID signal. In some examples, the refresh controller 916 can coordinate refresh operations with the host device so the system can continue to operate but without trying to access memory that is in the process of being refreshed.

In some examples, the refresh controller 916 can operate autonomously with respect to the host device. In such examples, the refresh controller 916 can return an error indication of the host device requests access to memory that is in the process of being refreshed. In some examples, the refresh controller 916 can move information around to allow the refresh operation to work seamlessly in the background without disruption of the operations of the host device.

In certain examples, the refresh controller 916 can be responsive to a host entering a sleep mode and can mange the refresh operation during the sleep mode. Such a refresh scheme can save a portion of the refresh power budget by using the smaller and more efficient refresh controller 916 of the buffer device 900 to manage refresh operations instead of a larger, power-consuming processor of the host device such as a memory controller. In some examples, the refresh controller 916 can be responsive to specific refresh commands receive from the host device and can refresh memory cells as directed by the host device.

In some examples, the refresh controller 916 can operate in response to operations of BIST logic 318. For example, BIST logic 318 may identify one or more performance metrics of the memory device, or of an individual region of the memory device. In such examples, BIST logic 318 can identify such performance metrics, for example, at a boot time, or during operation of the device. As examples, BIST logic 318 may identify a performance metric indicating that some regions of the memory device, for example even those associated with a single word line, are experiencing, or at risk of experiencing, a number of errors outside of an acceptable range. For example, in systems in which ECC is implemented, BIST logic 318 may identify regions of one or multiple memory devices as experiencing errors that are either uncorrectable, or of a number that approaches being uncorrectable. As a result, the refresh controller 916 may refresh such regions at a different, quicker, rate than other regions are refreshed. In another example, BIST logic 318 may identify a performance metric that a memory die, or a portion of a memory die, is operating at a temperature different than other portions of the multiple memory devices. For example, in a stack of memory devices, a memory device within the stack may operate at relatively elevated temperature relative to more outwardly placed devices. In other examples, and elevated temperature may result from an abnormally high number of memory region accesses. Because such elevated temperatures may promote undesirable leakage from the storage device, in response to BIST logic 318 identifying and elevated temperature region, the refresh rate may be increased to overcome the potential increased leakage. In some examples, BIST logic 318 may determine that errors of the memory device region are below an expected threshold; which may indicate that the refresh rate may be relaxed, to decrease power usage. BIST logic 318 may be configured to test a variety of memory cell operations and take appropriate corrective actions. When the tests identify performance metrics which may be improved through a change in the refresh rate, refresh controller 916 may make such adjustments as are appropriate.

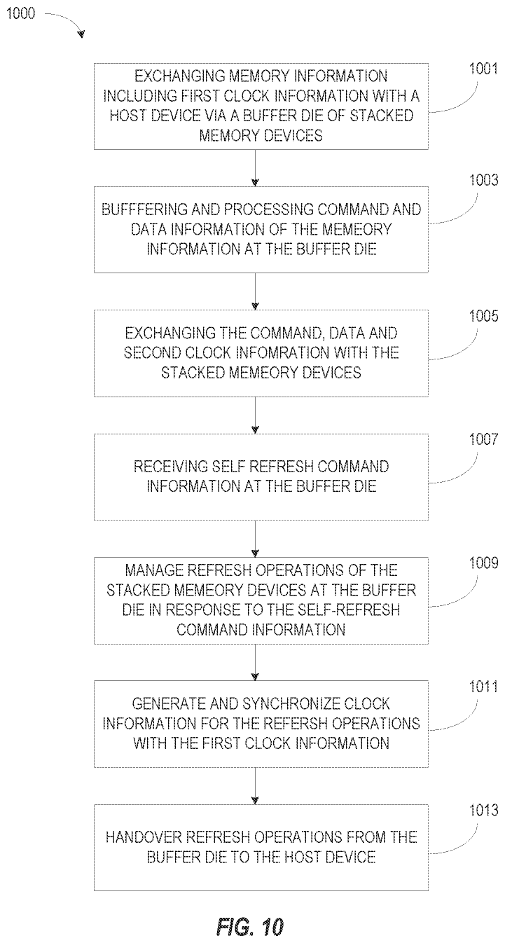

FIG. 10 illustrates generally an example method 1000 of operating a buffer die. At 1001, the buffer die can exchange command, data, and first clock information with a host device at multiple channels having a first width. At 1003, the command and data information can be buffered and processed at the buffer die. At 1005, the buffer die exchanges the command, the data, and second clock information with sets of memory devices stacked upon the buffer die using multiple channels having a second, larger width. At 1007, the buffer die can receive and intercept self-refresh command information from the host device for one or more of the memory devices. Such self-refresh commands can be issued when a portion of the overall system or the host device enters a sleep mode or a low-power mode. At 1009, the buffer die can manage refresh operations for the one or more memory devices in response to the self-refresh command information. In certain examples, the buffer die can generate synchronized self-refresh clock information for each memory device of the one or more memory devices in response to the self-refresh command information. In certain examples, while the host device is in a sleep mode, the first clock information may not be received at the buffer die or may not be received at one or more channels of the buffer die. At 1011, the buffer die can synchronize the self-refresh clock information with the first clock information at the conclusion of a self-refresh interval of the one or more memory devices. At 1013, the buffer can handover management of refresh operations to the host device in response to the conclusion of the self-refresh interval. In some examples, the refresh interval terminates in response to a command received from the host device. In some examples, the self-refresh interval terminates upon expiration of a timer.

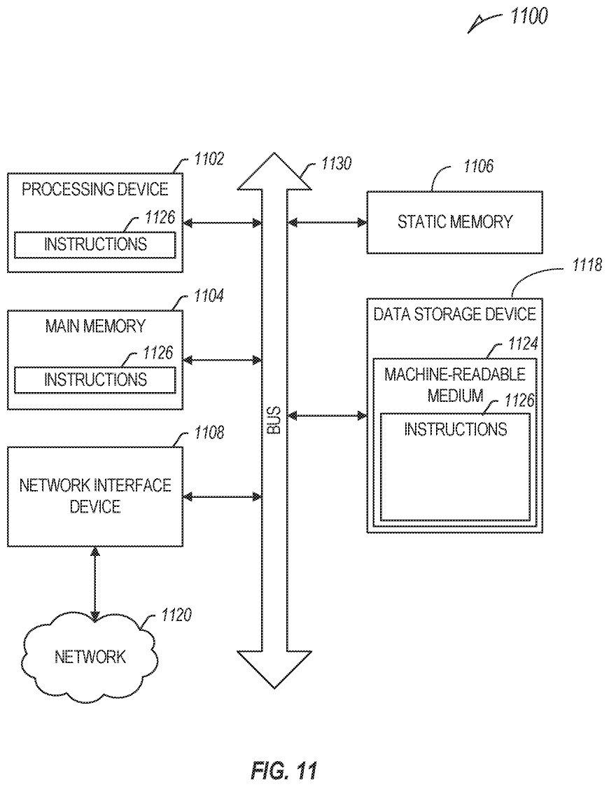

FIG. 11 illustrates a block diagram of an example machine (e.g., a host system) 1100 which may include one or more memory devices and/or systems as described above. In alternative embodiments, the machine 1100 may operate as a standalone device or may be connected (e.g., networked) to other machines. In a networked deployment, the machine 1100 may operate in the capacity of a server machine, a client machine, or both in server-client network environments. In an example, the machine 1100 may act as a peer machine in peer-to-peer (P2P) (or other distributed) network environment. The machine 1100 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 1100 may include a processing device 1102 (e.g., a hardware processor, a central processing unit (CPU), a graphics processing unit (GPU), a hardware processor core, or any combination thereof, etc.), a main memory 1104 (e.g., read-only memory (ROM), dynamic random-access memory (DRAM) such as synchronous DRAM (SDRAM) or Rambus DRAM (RDRAM), etc.), a static memory 1106 (e.g., static random-access memory (SRAM), etc.), and a storage system 1118, some or all of which may communicate with each other via a communication interface (e.g., a bus) 1130. In one example, the main memory 1104 includes one or more memory devices as described in examples above.

The processing device 1102 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 1102 can also be one or more special-purpose processing devices such as an application specific integrated circuit (ASIC), a field programmable gate array (FPGA), a digital signal processor (DSP), network processor, or the like. The processing device 1102 can be configured to execute instructions 1126 for performing the operations and steps discussed herein. The computer system 1100 can further include a network interface device 1108 to communicate over a network 1120.

The storage system 1118 can include a machine-readable storage medium (also known as a computer-readable medium) on which is stored one or more sets of instructions 1126 or software embodying any one or more of the methodologies or functions described herein. The instructions 1126 can also reside, completely or at least partially, within the main memory 1104 or within the processing device 1102 during execution thereof by the computer system 1100, the main memory 1104 and the processing device 1102 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 1100 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 1100 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 1126 (e.g., software, programs, an operating system (OS), etc.) or other data are stored on the storage system 1118 can be accessed by the main memory 1104 for use by the processing device 1102. The main memory 1104 (e.g., DRAM) is typically fast, but volatile, and thus a different type of storage than the storage system 1118 (e.g., an SSD), which is suitable for long-term storage, including while in an “off” condition. The instructions 1126 or data in use by a user or the machine 1100 are typically loaded in the main memory 1104 for use by the processing device 1102. When the main memory 1104 is full, virtual space from the storage system 1118 can be allocated to supplement the main memory 1104; however, because the storage system 1118 device is typically slower than the main memory 1104, and write speeds are typically at least twice as slow as read speeds, use of virtual memory can greatly reduce user experience due to storage system latency (in contrast to the main memory 1104, e.g., DRAM). Further, use of the storage system 1118 for virtual memory can greatly reduce the usable lifespan of the storage system 1118.

The instructions 1124 may further be transmitted or received over a network 1120 using a transmission medium via the network interface device 1108 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 1108 may include one or more physical jacks (e.g., Ethernet, coaxial, or phone jacks) or one or more antennas to connect to the network 1120. In an example, the network interface device 1108 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 1100, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

Operating a memory cell, as used herein, includes reading from, writing to, or erasing the memory cell. The operation of placing a memory cell in an intended state is referred to herein as “programming,” and can include both writing to or erasing from the memory cell (i.e., the memory cell may be programmed to an erased state).

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Example 1 is an apparatus, comprising: a buffer device supported by a substrate, the buffer device including a host device interface, and a dynamic random-access memory (DRAM) interface; multiple DRAM dies supported by the substrate; wherein the buffer device includes, buffer circuitry configured to operate the host device interface at a first data speed, and to operate the DRAM interface at a second data speed, slower than the first data speed; and refresh control circuitry configured to control refresh of memory cells of at least a portion of the multiple DRAM dies.

In Example 2, the subject matter of Example 1 includes, wherein the buffer device is configured to intercept a self-refresh signal received through the host device interface, and in response to that self-refresh signal, to control refresh of one or more of the multiple DRAM dies.

In Example 3, the subject matter of Examples 1-2 includes, wherein the buffer device also includes built in self-test (BIST) circuitry configured to identify performance metrics of one or more of the multiple DRAM dies.

In Example 4, the subject matter of Example 3 includes, wherein the refresh control circuitry is configured to control refresh of at least a portion of one or more of the multiple DRAM dies in response to an identified performance metric of such portion.

In Example 5, the subject matter of Examples 1-4 includes, wherein the refresh control circuitry is configured to identify the host entering a reduced power mode, and in response to the identification to initiate control of refresh of one or more of the multiple DRAM dies.

In Example 6, the subject matter of Examples 1-5 includes, wherein the multiple DRAM dies are configured to provide multiple ranks of memory.

In Example 7, the subject matter of Example 6 includes, wherein the memory cells of the at least portion of the multiple DRAM dies form a single rank of the multiple ranks of memory.

In Example 8, the subject matter of Examples 1-7 includes, wherein the buffer die is located at least partially underneath the multiple DRAM dies.

In Example 9, the subject matter of Example 8 includes, wherein the buffer die is located at least partially underneath a portion of each stack of two stacks of the multiple DRAM dies.

In Example 10, the subject matter of Examples 1-9 includes, wherein the multiple DRAM dies comprise a stack of DRAM dies coupled to a single buffer die.

In Example 11, the subject matter of Examples 1-10 includes, wherein the circuitry in the buffer die is configured to operate using a pulse amplitude modulation (PAM) protocol at the host device interface or the DRAM interface, or both.

Example 12 is a method, comprising: exchanging data between a host processor and a buffer at a first data speed; exchanging data between the buffer and multiple DRAM dies at a second data speed, slower than the first data speed; and through control of refresh circuitry of the buffer, on identification of an event, initiating control of refresh of one or more of the multiple DRAM dies.

In Example 13, the subject matter of Example 12 includes, wherein controlling refresh of one or more of the multiple DRAM dies includes initiating the refresh in response to a signal received from the host processor.

In Example 14, the subject matter of Examples 12-13 includes, wherein controlling refresh of one or more of the multiple DRAM dies includes controlling refresh of the one or more DRAM dies autonomously from the host processor.

In Example 15, the subject matter of Examples 12-14 includes, wherein controlling refresh of one or more of the multiple DRAM dies includes refreshing a first rank of memory of the multiple DRAM dies.

In Example 16, the subject matter of Examples 12-15 includes, wherein controlling refresh of one or more of the multiple DRAM dies includes refreshing a first bank of memory of the multiple DRAM dies.

In Example 17, the subject matter of Examples 12-16 includes, wherein controlling refresh of one or more of the multiple DRAM dies includes exchanging status information about the refresh of the one or more DRAM dies with the host.

In Example 18, the subject matter of Examples 12-17 includes, wherein the buffer includes a host device interface; and wherein the buffer is configured to intercept a self-refresh signal received through the host device interface, and in response to that self-refresh signal, to control refresh of one or more of the multiple DRAM dies.

In Example 19, the subject matter of Examples 12-18 includes, wherein the buffer includes built in self-test (BIST) circuitry configured to identify performance metrics of one or more of the multiple DRAM dies; and wherein refresh control circuitry of the buffer is configured to control refresh of at least a portion of the multiple DRAM dies in response to an identified performance metric of such portion.

In Example 20, the subject matter of Examples 12-19 includes, wherein the refresh control circuitry is configured to identify the host entering a reduced power mode, and in response to the identification to initiate control of refresh of one or more of the multiple DRAM dies.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An apparatus, comprising:
a buffer device supported by a substrate, the buffer device including a host device interface, and a dynamic random-access memory (DRAM) interface;
multiple DRAM dies supported by the substrate;
wherein the buffer device includes,
buffer circuitry configured to operate the host device interface at a first data speed, and to operate the DRAM interface at a second data speed, slower than the first data speed; and
refresh control circuitry configured to control refresh of memory cells of at least a portion of the multiple DRAM dies.

2. The apparatus of claim 1, wherein the buffer device is configured to intercept a self-refresh signal received through the host device interface, and in response to that self-refresh signal, to control refresh of one or more of the multiple DRAM dies.

3. The apparatus of claim 1, wherein the buffer device also includes built in self-test (BIST) circuitry configured to identify performance metrics of one or more of the multiple DRAM dies.

4. The apparatus of claim 3, wherein the refresh control circuitry is configured to control refresh of at least a portion of one or more of the multiple DRAM dies in response to an identified performance metric of such portion.

5. The apparatus of claim 1, wherein the refresh control circuitry is configured to identify the host entering a reduced power mode, and in response to the identification to initiate control of refresh of one or more of the multiple DRAM dies.

6. The apparatus of claim 1, wherein the multiple DRAM dies are configured to provide multiple ranks of memory.

7. The apparatus of claim 6, wherein the memory cells of the at least portion of the multiple DRAM dies form a single rank of the multiple ranks of memory.

8. The apparatus of claim 1, wherein the buffer die is located at least partially underneath the multiple DRAM dies.

9. The apparatus of claim 8, wherein the buffer die is located at least partially underneath a portion of each stack of two stacks of the multiple DRAM dies.

10. The apparatus of claim 1, wherein the multiple DRAM dies comprise a stack of DRAM dies coupled to a single buffer die.

11. The apparatus of claim 1, wherein the circuitry in the buffer die is configured to operate using a pulse amplitude modulation (PAM) protocol at the host device interface or the DRAM interface, or both.

12. A method, comprising:
exchanging data between a host processor and a buffer at a first data speed;
exchanging data between the buffer and multiple DRAM dies at a second data speed, slower than the first data speed; and
through control of refresh circuitry of the buffer, on identification of an event, initiating control of refresh of one or more of the multiple DRAM dies.

13. The method of claim 12, wherein controlling refresh of one or more of the multiple DRAM dies includes initiating the refresh in response to a signal received from the host processor.

14. The method of claim 12, wherein controlling refresh of one or more of the multiple DRAM dies includes controlling refresh of the one or more DRAM dies autonomously from the host processor.

15. The method of claim 12, wherein controlling refresh of one or more of the multiple DRAM dies includes refreshing a first rank of memory of the multiple DRAM dies.

16. The method of claim 12, wherein controlling refresh of one or more of the multiple DRAM dies includes refreshing a first bank of memory of the multiple DRAM dies.

17. The method of claim 12, wherein controlling refresh of one or more of the multiple DRAM dies includes exchanging status information about the refresh of the one or more DRAM dies with the host.

18. The method of claim 12, wherein the buffer includes a host device interface; and
wherein the buffer is configured to intercept a self-refresh signal received through the host device interface, and in response to that self-refresh signal, to control refresh of one or more of the multiple DRAM dies.

19. The method of claim 12, wherein the buffer includes built in self-test (BIST) circuitry configured to identify performance metrics of one or more of the multiple DRAM dies; and
wherein refresh control circuitry of the buffer is configured to control refresh of at least a portion of the multiple DRAM dies in response to an identified performance metric of such portion.

20. The method of claim 12, wherein the refresh control circuitry is configured to identify the host entering a reduced power mode, and in response to the identification to initiate control of refresh of one or more of the multiple DRAM dies.
